(19) United States
(12) Patent Application Publication
(10) Pub. No.: US 2026/0184275 A1
(43) Pub. Date: Jul. 2, 2026

(54) HIGH EFFICIENCY REGULATOR

(71) Applicants: Joshua T. Weed, Stacy, MN (US); Jeremy Winter, Maple Grove, MN (US); Matthew Graser, Wyoming, MN (US)

(72) Inventors: Joshua T. Weed, Stacy, MN (US); Jeremy Winter, Maple Grove, MN (US); Matthew Graser, Wyoming, MN (US)

(21) Appl. No.: 19/431,803

(22) Filed: Dec. 23, 2025

Related U.S. Application Data
(60) Provisional application No. 63/739,720, filed on Dec. 30, 2024.

(51) Int. Cl. B60R 16/03; H02M 1/08; H02M 1/36; H02M 3/158; H03K 7/08

(52) U.S. Cl. CPC B60R 16/0307; H02M 1/08; H02M 1/36; H02M 3/1582; H03K 7/08

(57) ABSTRACT

A power supply circuit is provided, comprising: an alternating current generator (“ACG”); a rectifier/regulator to convert one or more phase AC voltage from the ACG into a DC output voltage; a converter to decouple the DC output voltage from a load voltage provided to a battery coupled to an output of the converter; and a controller. The converter comprises: a switch having an input coupled to the DC output voltage, an output, and a control input; an inductor coupled between the switch output and the converter output; a diode coupled between the switch output and the converter output; and a capacitor coupled between the converter output and ground. The controller is configured to provide control signals to the switch control input to control a ratio of an ON state and an OFF state of the switch, thereby regulating the DC output voltage of the rectifier/regulator to the load voltage.

### PRIORITY CLAIM

This application claims the benefit of priority to U.S. Provisional Patent Application No. 63/739,720 , filed Dec. 30, 2024, and titled “HIGH EFFICIENCY REGULATOR”, which is incorporated herein by reference in its entirety.

### FIELD OF THE DISCLOSURE

The present disclosure relates generally to regulators and more particularly to high efficiency regulators to decouple input voltage levels supplied by a

rectification circuit from output voltage levels provided to a battery, thereby permitting an alternating current generator to operate at higher variable voltage levels and lower currents, resulting in less generated heat.

### BACKGROUND

It is known to provide a regulator circuit having rectification circuitry to convert AC power from an alternating current generator on a vehicle to DC power and regulation circuitry to maintain the DC voltage at a nominal level, such as the voltage of the vehicle battery. Some known regulation circuitry also monitors the rectification circuitry to ensure that excess current from the AC voltages is routed to ground or otherwise managed to maintain the DC voltage at a safe level for the battery. Typical regulator circuits provide low DC voltage output to the battery, which requires high current operation at the rectification circuitry, which, along with the high current operation of the AC power source (e.g., an alternating current generator or “ACG”) in turn generates significant, undesirable heat.

Thus, it is desirable to provide a high efficiency regulator circuit that permits the rectification circuitry to operate at higher voltages, and correspondingly lower currents, while providing the same lower DC output voltage to the battery. In other words, it is desirable to decouple the input voltage levels supplied by the rectification circuitry from the output voltage levels provided to the battery, thereby permitting the ACG and rectification circuitry to operate at higher variable voltage levels instead of the battery voltage, which results in lower current operation and less generated heat.

### SUMMARY

According to one embodiment of the present disclosure, a high efficiency power supply circuit for a vehicle is provided, comprising: an alternating current generator (“ACG”) configured to convert mechanical energy from an engine of the vehicle into one or more phase alternating current (“AC”) voltage; a rectifier/regulator coupled to the ACG and configured to convert the one or more phase AC voltage into a direct current (“DC”) output voltage; a converter coupled to the rectifier/regulator and configured to decouple the DC output voltage from a load voltage provided to a battery coupled to an output of the converter; and a controller coupled to the converter; wherein the converter comprises: a switch having an input coupled to the DC output voltage, an output, and a control input coupled to the controller; an inductor coupled between the output of the switch and the output of the converter; a diode coupled between the output of the switch and the output of the converter; and a capacitor having a first node coupled to the output of the converter and a second node coupled to ground; and wherein the controller is configured to provide control signals to the control input of the switch to control a ratio of an ON state of the switch and an OFF state of the switch, thereby regulating the DC output voltage of the rectifier/regulator to the load voltage. In one aspect of this embodiment, the high efficiency power supply circuit further comprises a fuse connected between a positive terminal of the battery and the output of the converter. In another aspect, the converter is a buck-boost converter, wherein a first node of the inductor is coupled to the output of the switch and the second node of the inductor is coupled to ground, and a cathode of the diode is coupled to the output of the switch and an anode of the diode is coupled to the output of the converter. In yet another aspect, the switch is a power MOSFET. In another aspect, the controller is configured to adjust one of a pulse width or a duty cycle of the control signals to adjust the load voltage. In another aspect, the ACG operates at a higher variable voltage level than the load voltage. In still another aspect, the controller is configured to delay operation of the converter after the engine is started for either a predetermined period of time or until the engine reaches a predetermined speed. In another aspect of this embodiment, the controller is configured to control operation of the converter to control a ramp rate of power supplied by the circuit, which in turn controls a ramp rate of torque on the engine. In another aspect, the controller is configured to control the converter to provide a first load voltage for a battery of a first type and a second load voltage for a battery of a second type.

In another embodiment, the present disclosure provides a high efficiency power supply circuit for a vehicle, comprising: an alternating current generator (“ACG”); a rectifier/regulator configured to convert one or more phase AC voltage from the ACG into a direct current (“DC”) output voltage; a converter configured to decouple the DC output voltage from an output voltage of the converter; a battery coupled to the output voltage of the converter; and a controller; wherein the converter comprises: a switch having an input coupled to the DC output voltage, an output, and a control input coupled to the controller; an inductor coupled between the output of the switch and the output of the converter; a diode coupled between the output of the switch and the output of the converter; and a capacitor coupled between the output of the converter and ground; and wherein the controller is configured to provide control signals to the control input of the switch to control a ratio of an ON state of the switch and an OFF state of the switch, thereby regulating the DC output voltage of the rectifier/regulator to the output voltage of the converter. In one aspect of this embodiment, the diode includes a cathode coupled to the output of the switch and an anode coupled to the output of the converter and the inductor includes a first node coupled to the output of the switch and a second node coupled to ground. In another aspect, the high efficiency power supply circuit further comprises a fuse connected between a positive terminal of the battery and the output of the converter. In yet another aspect, the converter is a buck converter wherein the inductor includes a first node coupled to the output of the switch and a second node coupled to the output of the converter and the diode includes a cathode coupled to the output of the switch and an anode coupled to ground. In still another aspect, the switch is a power MOSFET. In another aspect of this embodiment, the controller is configured to adjust one of a pulse width or a duty cycle of the control signals to adjust the output voltage of the converter. In another aspect, the ACG operates at a higher variable voltage level than the output voltage of the converter. In another aspect, the controller is configured to delay operation of the converter after an engine of the vehicle is started for either a predetermined period of time or until the engine reaches a predetermined speed. In yet another aspect, the controller is configured to control operation of the converter to control a ramp rate of power supplied by the circuit, which in turn controls a ramp rate of torque on an engine of the vehicle. In another aspect, the controller is configured to control the converter to provide a first output voltage for a battery of a first type and a second output voltage for a battery of a second type.

In yet another embodiment, the present disclosure provides a method of supplying power to a vehicle, comprising: converting, by an alternating current generator (“ACG”) mechanical energy from an engine of the vehicle into one or more phase alternating current (“AC”) voltage; converting, by a rectifier/regulator coupled to the ACG, the one or more phase AC voltage into a direct current (“DC”) output voltage; decoupling, by a converter coupled to the rectifier/regulator, the DC output voltage from a load voltage provided by the converter to a battery coupled to an output of the converter; wherein the converter comprises: a switch having an input coupled to the DC output voltage, an output, and a control input; an inductor coupled between the output of the switch and the output of the converter; a diode coupled between the output of the switch and the output of the converter; and a capacitor coupled between the output of the converter and ground; and providing, by a controller, control signals to the control input of the switch to control a ratio of an ON state of the switch and an OFF state of the switch, thereby regulating the DC output voltage of the rectifier/regulator to the load voltage.

### BRIEF DESCRIPTION OF THE DRAWINGS

The above-mentioned and other advantages and objects of this disclosure, and the manner of attaining them, will become more apparent, and the disclosure itself will be better understood, by reference to the following description of embodiments of the invention taken in conjunction with the accompanying drawings, wherein:

FIG. 1 is a schematic diagram of a conventional power supply circuit for a vehicle;

FIG. 2 is a schematic diagram of a high efficiency power supply circuit for a vehicle according to one embodiment of the present disclosure;

FIG. 3 is a more detailed schematic diagram of the high efficiency power supply circuit of FIG. 2;

FIG. 4 is a schematic diagram of another embodiment of the high efficiency power supply circuit of FIG. 2; and

FIG. 5 is a graph depicting the operation range in terms of output power from the ACG vs. load voltage of the circuit of FIG. 1 and the circuit of FIGS. 2 and 3.

Corresponding reference characters indicate corresponding parts throughout the several views. Although the drawings represent embodiments of the present disclosure, the drawings are not necessarily to scale, and certain features may be exaggerated or omitted in some of the drawings in order to better illustrate and explain the present disclosure.

### DETAILED DESCRIPTION

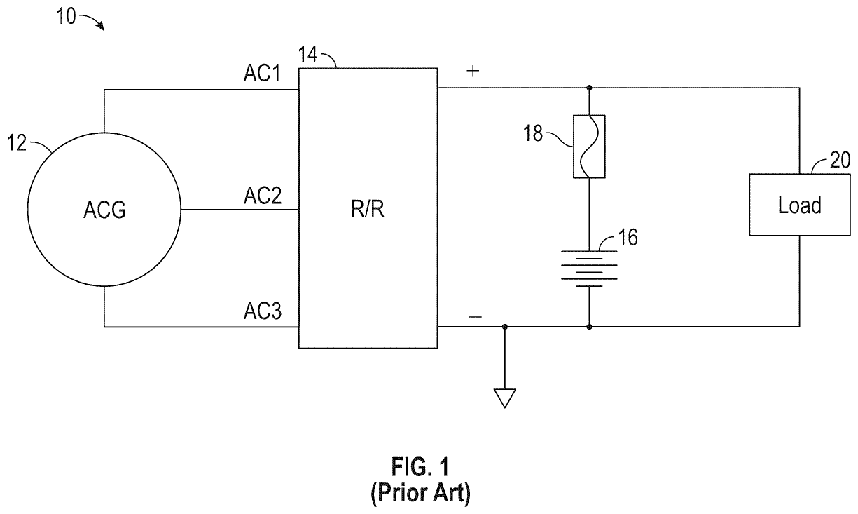

Referring now to FIG. 1, a schematic diagram of a conventional power supply circuit 10 for a vehicle is shown. The vehicle may be any type of vehicle such as off-road vehicles that are exposed to harsh off-road environments in terms of extreme temperatures, as well as exposure to water, salt, chemicals, vibration, etc. The power supply circuit 10 generally includes an alternating current generator (“ACG 12”), a rectifier/regulator (“R/R 14”), a battery 16, a fuse 18 and a load 20. The ACG 12 converts mechanical energy supplied by a prime mover (e.g., an engine) of a vehicle (not shown) into electrical energy to charge the vehicle battery 16 during engine operation and to power the load 20 (i.e., electronic devices on the vehicle). As is known in the art, a typical three-phase ACG 12 includes a rotor with magnets or electromagnets inside and a stator with three-phase stator windings. When the vehicle engine starts, the crankshaft rotates, which in turn drives rotation of the rotor. The magnetic poles of the rotor interact with the magnetic field of the stator windings as the rotor rotates. The changing position of the rotor magnets relative to the stator windings creates an induced current in the stator windings, which is provided as three AC voltages with a phase difference between each of 120 degrees. These AC voltages are represented in FIG. 1 as AC1, AC2 and AC3.

The AC voltages AC1, AC2, and AC3 are converted by the rectifier portion of the R/R 14 into a direct current or DC voltage, which, after smoothing using a capacitor, is transferred to the battery 16 through the fuse 18 and used to power the electrical components of the vehicle (i.e., the load 20). The AC voltages AC1, AC2, and AC3 are also monitored by the regulator portion of the R/R 14 to ensure that excess current from the AC voltages is provided to ground or open circuited, thereby maintaining the DC voltage within safe levels for the battery 16 and other electrical components of the vehicle, such as approximately 14 VDC.

In the conventional power supply circuit 10 of FIG. 1, the ACG 12 and the R/R 14 are configured to operate at the same voltage as required by the battery 16 and the load(s) 20, which in certain applications is approximately 14 VDC on the DC side and correspondingly a slightly higher unrectified AC voltage on the AC side. The 14 VDC supplied to the battery 16 typically requires 100 A operation of the ACG 12. In other applications, 45 A to 85 A (corresponding to 660 W to 1220 W, respectively) operation of the ACG 12 may be used. Other systems may operate in a range of 118 A to 125 A (corresponding to 1700 W to 1800 W, respectively). Regulation by the R/R 14 of this high current operation generates significant heat, which has a variety of undesirable effects as is further described below.

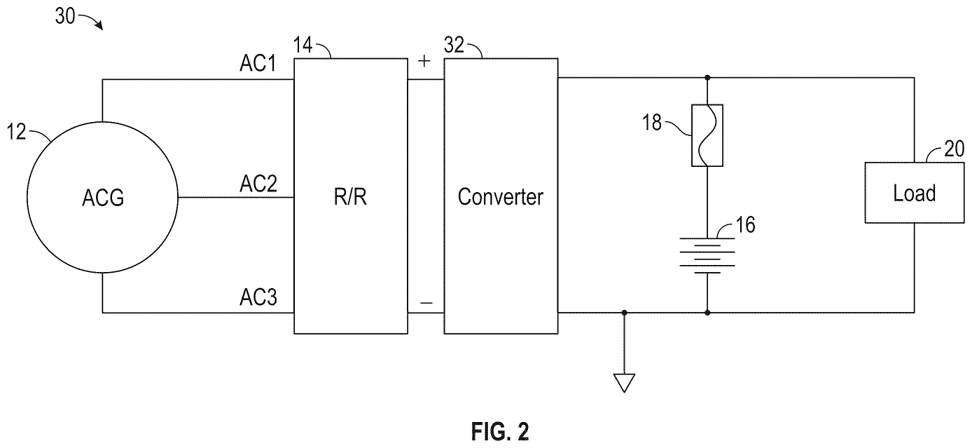

FIG. 2 provides a schematic diagram of a high efficiency power supply circuit for a vehicle (hereinafter, “the regulator 30”). The various components of the regulator 30 that are the same as those shown in FIG. 1 are labeled with the same reference numbers. In the regulator 30, a DC-to-DC regulator or converter 32 is connected across the positive and negative terminals of the R/R 14 and configured to provide DC voltage to the battery 16 (through the fuse 18) and the load 20. In certain embodiments, the converter 32 is a buck-boost converter which functions as a switching regulator that allows the R/R 14 to operate at a much higher voltage while providing the same lower DC output voltage to the battery 16 and the load 20. In other embodiments, the converter 32 is a buck converter. The converter 32 decouples the input voltage levels supplied by the R/R 14 from the output voltage levels provided to the battery 16 and the load 20. This permits the ACG 12 and the R/R to operate at higher variable voltage levels instead of the nominal DC voltage level of the electrical components of the vehicle. The higher variable voltage operation of the ACG 12 allows for substantially lower current operation, which increases the efficiency of the ACG 12 and R/R 14, resulting in less resistive energy loss (i.e., less generated heat) or increased power.

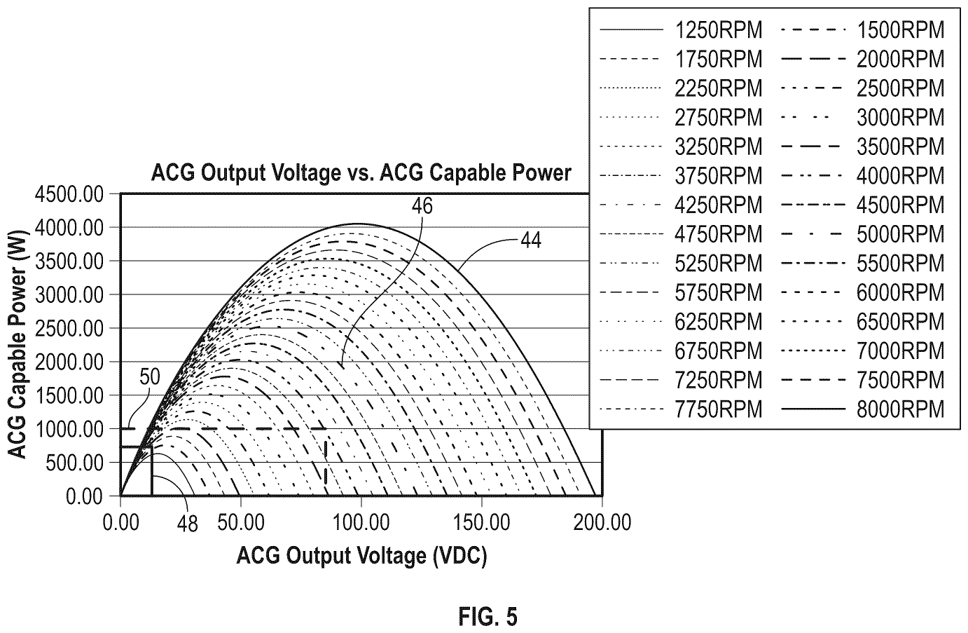

More specifically, the amount of heat generated is reduced for the same power output because of the higher voltage, lower current operation. For example, the heat is reduced when the ACG 12 and the R/R 14 are operated at 14.4V and 35 A (500 W power) or at 30V and 16 A (500 W power) due to the heat loss being equal to the current squared times the resistance. On the other hand, changing the operating voltage of the ACG 12 also changes the amount of power produced (i.e., at 14.4V operation 500 W power may be produced and at 30V operation, 1000 W power may be produced). These various power outputs are shown in FIG. 5 and described below. Thus, higher variable voltage operation either results in less heat for the same amount of power or additional power.

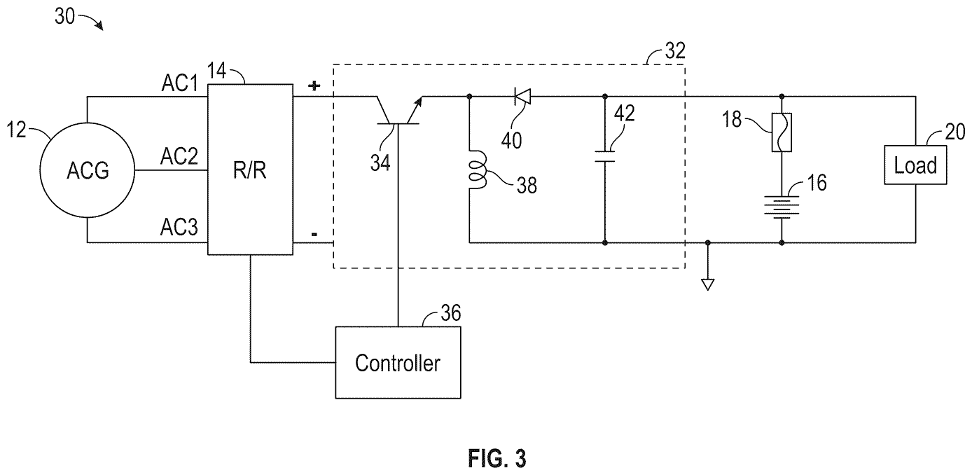

FIG. 3 depicts an example configuration of the converter 32. As shown, a switch 34 is connected to the positive output voltage from the R/R 14. The switch 34 could be any type of electronic power switch such as a bipolar transistor, a power MOSFET or another device that can be controlled to conduct the inlet voltage when in an ON state and not conduct the input voltage when in an OFF state. The operation of the switch 34 is controlled by a controller 36, which may provide a high-speed pulsating signal from an oscillator circuit to the control input of the switch 34. The output of the switch 34 is connected to one node of an inductor 38, the other node of which is connected to ground. The output of the switch 34 is also connected to the cathode of a diode 40. The anode of the diode 40 is connected to one node of a capacitor 42, the other node of which is connected to ground. The voltage across the capacitor 42 is provided to the battery 16 (through the fuse 18) and the load 20.

In operation, when the switch 34 is in the ON state, current flows through the switch 34 and instantaneously through the inductor 38, as the diode 40 is inversely polarized. The inductor 38 limits and stores a certain amount of the current. When the controller 36 causes the switch 34 to move to the OFF state, blocking the normal passage of input current from the R/R 14, the inductor 38 provides its stored current to the diode 40 and thus to the output of the converter 32. The current is also stored by the capacitor 42. During the next ON state of the switch 34, the cycle repeats, but this time without current in the inductor 38, it is the capacitor 42 that supplies the stored energy to the output of the converter 32.

By controlling the ratio of the ON state to the OFF state of the switch 34 (i.e., by adjusting the pulse width or duty cycle of the control signal from the controller 36), the output voltage of the converter 32 is determined. As such, by providing the switch 34 with the appropriate control signal, the current operating voltage of the ACG 12 and R/R 14 can be regulated to a desired voltage such as approximately 14 VDC. For example, when the ACG 12 provides AC voltages AC1, AC2, and AC3 at 25 amps and the R/R 14 rectifies and regulates the incoming power to 60 VDC, the converter 32 can be controlled to provide 14 VDC at 100 amps to the battery 16 and the load 20.

In some examples, the rectification strategy of the regulator (e.g., the regulator portion of the R/R 14) uses a field-oriented control (FOC) motor control, such as with the use of Field Effect Transistors (FETs), instead of using maximum power point control from Silicon Controlled Rectifiers (SCRs). This rectification strategy can provide a number of added benefits, including: higher total system power due to the active rectification of FOC; higher ACG voltage control via higher switching frequency; higher regulator efficiency/thermal efficiency via FETs versus SCRs; the capability to boost ACG input voltage; and open circuit ACG voltage suppression.

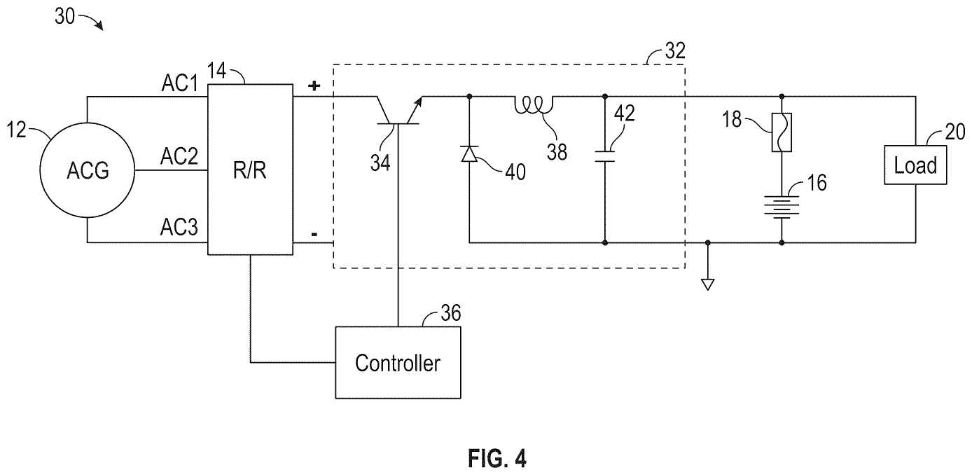

FIG. 4 depicts another example of the converter 32 implemented as a buck converter. In this example, the circuit locations of the diode 40 and the inductor 38 are reversed relative to the circuit locations of FIG. 3. The description above with reference to the buck-boost converter 32 of FIG. 3 applies equally to the converter 32 of FIG. 4 with the exception of the locations of these components.

As indicated above, the ability to regulate the output voltage of the converter 32 allows the ACG 12 to operate at higher variable voltage levels instead of the nominal DC voltage level of the electrical components of the vehicle. The higher voltage levels permit the ACG 12 to operate at much lower current levels, where the ACG 12 is much more efficient (i.e., loses less energy to heat) and can generate more power. This greater efficiency and the corresponding lower heat may provide a variety of advantages. As the ACG 12 is cooled, at least in part by engine oil, the higher voltage and lower current operation may result in several hundreds of watts lower heat rejection from the stator of the ACG 12 to the engine oil. The lower heat loading on the engine oil may result in longer oil life. Additionally, the lower heat loading may result in a reduction in the engine power lost to heat. Moreover, the decreased engine oil heat allows for lower heat rejection from the engine oil to the engine coolant, which results in decreased heat rejection requirements from the engine radiator and the radiator fan. This may lead to lower power consumption by the engine radiator and the radiator fan, leaving more power available for other features/functions of the vehicle. Additionally, the package size of the system may be reduced (e.g., smaller and lighter) for a given power output (i.e., lower engine inertia, more room for other components) and fewer and less expensive materials may be used (i.e., ferrite magnets, smaller wire, etc.).

As the regulator 30 requires less cooling for the same amount of power output, it may be moved from its typical location in front of the vehicle radiator to take advantage of the air flow to another location on the vehicle, resulting in greater air flow to the radiator. The flexibility of relocating the regulator 30 may result in the use of significantly less wiring from the ACG 12 to the other components of the regulator 30. As this wiring is typically large gauge, even small reductions in length can provide a significant cost savings. In some vehicles, the engine is located at the rear of the vehicle while the radiator is located at the front of the vehicle. In such cases, the amount of wiring length may be substantial.

Referring now to FIG. 5, a graph showing the difference between the operating range 48 of a charging system using the conventional power supply circuit 10 of FIG. 1 as compared to the operation range 50 of a charging system using the high efficiency power supply circuit 30 of FIG. 2. The y-axis shows the output power of the ACG 12 (watts) and the x-axis shows the DC output voltage provided to the converter 32 (volts). The plurality of curves represents different operating ACG 12 speeds (rpm). For example, the curve 44 shows the relationship between output power and the DC R/R 14 output voltage for an ACG 12 operating at 8000 rpm. The curve 46 shows the relationship between output power and the DC R/R 14 output voltage for an ACG 12 operating at 5000 rpm. The boundary 48 shows the limits of the operation range of the conventional power supply circuit 10. As shown, the circuit 10 has an upper limit of the equivalent DC voltage it can operate the ACG 12 at and a maximum output power of approximately 700 W. The limits of the operation range of the high efficiency power supply regulator 30 (boundary 50), on the other hand, extend up to an ACG 12 equivalent DC voltage of approximately 80 VDC and an output power of over 1000 W. As shown, the ability to operate the ACG 12 at a higher variable voltage in the regulator 30 enables use of the full power capacity of the ACG 12. As the ACG 12 speed increases, the operating range of the AC 12 equivalent DC voltages increase. For a particular ACG 12 operating speed, there is a voltage operation point that produces peak power. The conventional circuit 10 operates far below this point producing sub-optimal power levels. The regulator 30 permits use of most of the voltage range from idle to the maximum ACG 12 speed.

In certain embodiments, CAN and ECU capabilities may be added to the regulator 30 or in a controller operably coupled to the regulator 30 to enable one or more of a plurality of smart features of a control system (e.g., provided with software or other implemented logic). For example, the control system may be configured such that the regulator 30 is able to calculate/estimate and/or respond to the torque/torque rate of the ACG 12 being applied to the engine and limit the torque based on presets and CAN messages. For instance, a regulator 30 or a controller may control the operation of the converter to control a ramp rate of power supplied by the regulator 30, where the ramp rate generally represents a (total change in output)/(time taken for the change). The control of the ramp rate of power supplied by the regulator 30 can then be used to control a ramp rate of torque on the engine.

Also, the control system may be configured to report the torque back to the engine management system. Additionally, the control system may be configured to limit output current and power to remain within certain levels. Further, the regulator 30 or a controller may be controlled to delay operation of the converter (and thus delay power generation) after the engine starts based on speed (rpm) (e.g., delay operation until the engine reaches a predetermined speed) or time (e.g., delay operation until the engine is started and is running for a predetermined period of time), which may improve the engine starting performance. In circumstances where the regulator 30 power output is changed to match the demand of the vehicle loads, the control system may limit how quickly the change occurs, which may improve the engine performance.

In applications where the vehicle has battery current monitoring capability, the control system may implement constant current charging and float current charging to extend the life of the battery. In other embodiments, the regulator 30 may be calibrated to have different target output voltages for different battery chemistries to extend the life of the battery. In other embodiments, the control system may implement a capability to switch between a bulk charging mode and a float charging mode based on a timer.

In other embodiments, the regulator 30 may detect and report faults, such as CAN faults, over/under voltages, internal hardware faults, temperature faults, and ACG 12 hardware faults, along with additional data (e.g., temperatures, currents, voltages, short circuit, open circuit, ACG input frequency/engine speed, output power, ACG input power, etc.) to improve diagnostics. In still other embodiments, the regulator 30 may implement various forms of output temperature compensation, so that the output voltage target remains the same across the operating temperature range.

In other embodiments, the control system may include a capability to auto-detect what ACG is connected to the regulator 30 and configure the software accordingly. Finally, in other embodiments, the controller 36 or other aspects of the control system may have the ability to be reflashable using a service tool or OTA if a calibration or software update is needed. This allows the regulator to be more versatile and similar/same hardware to be used between many different ACGs with minimal or no hardware changes.

### Additional Notes and Examples

Additional examples of the presently described embodiments include the following, non-limiting implementations. Each of the following non-limiting examples may stand on its own or may be combined in any permutation or combination with any one or more of the other examples provided below or throughout the present disclosure.

Example 1 is a high efficiency power supply circuit for a vehicle, comprising: an alternating current generator (“ACG”) configured to convert mechanical energy from an engine of the vehicle into one or more phase alternating current (“AC”) voltage; a rectifier/regulator coupled to the ACG and configured to convert the one or more phase AC voltage into a direct current (“DC”) output voltage; a converter coupled to the rectifier/regulator and configured to decouple the DC output voltage from a load voltage provided to a battery coupled to an output of the converter; and a controller coupled to the converter; wherein the converter comprises: a switch having an input coupled to the DC output voltage, an output, and a control input coupled to the controller; an inductor coupled between the output of the switch and the output of the converter; a diode coupled between the output of the switch and the output of the converter; and a capacitor having a first node coupled to the output of the converter and a second node coupled to ground; and wherein the controller is configured to provide control signals to the control input of the switch to control a ratio of an ON state of the switch and an OFF state of the switch, thereby regulating the DC output voltage of the rectifier/regulator to the load voltage.

In Example 2, the subject matter of Example 1 optionally includes a fuse connected between a positive terminal of the battery and the output of the converter.

In Example 3, the subject matter of any one or more of Examples 1-2 optionally include wherein the converter is a buck-boost converter, wherein a first node of the inductor is coupled to the output of the switch and the second node of the inductor is coupled to ground, and a cathode of the diode is coupled to the output of the switch and an anode of the diode is coupled to the output of the converter.

In Example 4, the subject matter of any one or more of Examples 1-3 optionally include wherein the switch is a power MOSFET.

In Example 5, the subject matter of any one or more of Examples 1-4 optionally include wherein the controller is configured to adjust one of a pulse width or a duty cycle of the control signals to adjust the load voltage.

In Example 6, the subject matter of any one or more of Examples 1-5 optionally include wherein the ACG operates at a higher variable voltage level than the load voltage.

In Example 7, the subject matter of any one or more of Examples 1-6 optionally include wherein the controller is configured to delay operation of the converter after the engine is started for either a predetermined period of time or until the engine reaches a predetermined speed.

In Example 8, the subject matter of any one or more of Examples 1-7 optionally include wherein the controller is configured to control operation of the converter to control a ramp rate of power supplied by the circuit, which in turn controls a ramp rate of torque on the engine.

In Example 9, the subject matter of any one or more of Examples 1-8 optionally include wherein the controller is configured to control the converter to provide a first load voltage for a battery of a first type and a second load voltage for a battery of a second type.

Example 10 is a high efficiency power supply circuit for a vehicle, comprising: an alternating current generator (“ACG”); a rectifier/regulator configured to convert one or more phase AC voltage from the ACG into a direct current (“DC”) output voltage; a converter configured to decouple the DC output voltage from an output voltage of the converter; a battery coupled to the output voltage of the converter; and a controller; wherein the converter comprises: a switch having an input coupled to the DC output voltage, an output, and a control input coupled to the controller; an inductor coupled between the output of the switch and the output of the converter; a diode coupled between the output of the switch and the output of the converter; and a capacitor coupled between the output of the converter and ground; and wherein the controller is configured to provide control signals to the control input of the switch to control a ratio of an ON state of the switch and an OFF state of the switch, thereby regulating the DC output voltage of the rectifier/regulator to the output voltage of the converter.

In Example 11, the subject matter of Example 10 optionally includes wherein the diode includes a cathode coupled to the output of the switch and an anode coupled to the output of the converter and the inductor includes a first node coupled to the output of the switch and a second node coupled to ground.

In Example 12, the subject matter of any one or more of Examples 10-11 optionally include a fuse connected between a positive terminal of the battery and the output of the converter.

In Example 13, the subject matter of any one or more of Examples 10-12 optionally include wherein the converter is a buck converter wherein the inductor includes a first node coupled to the output of the switch and a second node coupled to the output of the converter and the diode includes a cathode coupled to the output of the switch and an anode coupled to ground.

In Example 14, the subject matter of any one or more of Examples 10-13 optionally include wherein the switch is a power MOSFET.

In Example 15, the subject matter of any one or more of Examples 10-14 optionally include wherein the controller is configured to adjust one of a pulse width or a duty cycle of the control signals to adjust the output voltage of the converter.

In Example 16, the subject matter of any one or more of Examples 10-15 optionally include wherein the ACG operates at a higher variable voltage level than the output voltage of the converter.

In Example 17, the subject matter of any one or more of Examples 10-16 optionally include wherein the controller is configured to delay operation of the converter after an engine of the vehicle is started for either a predetermined period of time or until the engine reaches a predetermined speed.

In Example 18, the subject matter of any one or more of Examples 10-17 optionally include wherein the controller is configured to control operation of the converter to control a ramp rate of power supplied by the circuit, which in turn controls a ramp rate of torque on an engine of the vehicle.

In Example 19, the subject matter of any one or more of Examples 10-18 optionally include wherein the controller is configured to control the converter to provide a first output voltage for a battery of a first type and a second output voltage for a battery of a second type.

Example 20 is a method of supplying power to a vehicle, comprising: converting, by an alternating current generator (“ACG”) mechanical energy from an engine of the vehicle into one or more phase alternating current (“AC”) voltage; converting, by a rectifier/regulator coupled to the ACG, the one or more phase AC voltage into a direct current (“DC”) output voltage; decoupling, by a converter coupled to the rectifier/regulator, the DC output voltage from a load voltage provided by the converter to a battery coupled to an output of the converter; wherein the converter comprises: a switch having an input coupled to the DC output voltage, an output, and a control input; an inductor coupled between the output of the switch and the output of the converter; a diode coupled between the output of the switch and the output of the converter; and a capacitor coupled between the output of the converter and ground; and providing, by a controller, control signals to the control input of the switch to control a ratio of an ON state of the switch and an OFF state of the switch, thereby regulating the DC output voltage of the rectifier/regulator to the load voltage.

Any directional references used with respect to any of the figures, such as right or left, up or down, or top or bottom, are intended for convenience of description, and do not limit the present disclosure or any of its components to any particular positional or spatial orientation. Additionally, any reference to rotation in a clockwise direction or a counterclockwise direction is simply illustrative. Any such rotation may be implemented in the reverse direction as that described herein.

Although the foregoing text sets forth a detailed description of embodiments of the disclosure, it should be understood that the legal scope of the invention is defined by the words of the claims set forth at the end of this patent and equivalents. The detailed description is to be construed as exemplary only and does not describe every possible embodiment. Numerous alternative embodiments may be implemented, using either current technology or technology developed after the filing date of this patent, which would still fall within the scope of the claims.

The following additional considerations apply to the foregoing description. Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Unless specifically stated otherwise, use herein of words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

Additionally, some embodiments may be described using the expression “communicatively coupled,” which may mean (a) integrated into a single housing, (b) coupled using wires, or (c) coupled wirelessly (i.e., passing data/commands back and forth wirelessly) in various embodiments.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

In addition, use of the “a” or “an” are employed to describe elements and components of the embodiments herein. This is done merely for convenience and to give a general sense of the description. This description, and the claims that follow, should be read to include one or at least one and the singular also includes the plural unless it is obvious that it is meant otherwise.

The patent claims at the end of this patent application are not intended to be construed under 35 U.S.C. § 112(f) unless traditional means-plus-function language is expressly recited, such as “means for” or “step for” language being explicitly recited in the claim(s).

What is claimed is:

1. A high efficiency power supply circuit for a vehicle, comprising:
an alternating current generator (“ACG”) configured to convert mechanical energy from an engine of the vehicle into one or more phase alternating current (“AC”) voltage;
a rectifier/regulator coupled to the ACG and configured to convert the one or more phase AC voltage into a direct current (“DC”) output voltage;
a converter coupled to the rectifier/regulator and configured to decouple the DC output voltage from a load voltage provided to a battery coupled to an output of the converter; and
a controller coupled to the converter;
wherein the converter comprises:
a switch having an input coupled to the DC output voltage, an output, and a control input coupled to the controller;
an inductor coupled between the output of the switch and the output of the converter;
a diode coupled between the output of the switch and the output of the converter; and
a capacitor having a first node coupled to the output of the converter and a second node coupled to ground; and
wherein the controller is configured to provide control signals to the control input of the switch to control a ratio of an ON state of the switch and an OFF state of the switch, thereby regulating the DC output voltage of the rectifier/regulator to the load voltage.

2. The high efficiency power supply circuit of claim 1, further comprising a fuse connected between a positive terminal of the battery and the output of the converter.

3. The high efficiency power supply circuit of claim 1, wherein the converter is a buck-boost converter, wherein a first node of the inductor is coupled to the output of the switch and the second node of the inductor is coupled to ground, and a cathode of the diode is coupled to the output of the switch and an anode of the diode is coupled to the output of the converter.

4. The high efficiency power supply circuit of claim 1, wherein the switch is a power MOSFET.

5. The high efficiency power supply circuit of claim 1, wherein the controller is configured to adjust one of a pulse width or a duty cycle of the control signals to adjust the load voltage.

6. The high efficiency power supply circuit of claim 1, wherein the ACG operates at a higher variable voltage level than the load voltage.

7. The high efficiency power supply circuit of claim 1, wherein the controller is configured to delay operation of the converter after the engine is started for either a predetermined period of time or until the engine reaches a predetermined speed.

8. The high efficiency power supply circuit of claim 1, wherein the controller is configured to control operation of the converter to control a ramp rate of power supplied by the circuit, which in turn controls a ramp rate of torque on the engine.

9. The high efficiency power supply circuit of claim 1, wherein the controller is configured to control the converter to provide a first load voltage for a battery of a first type and a second load voltage for a battery of a second type.

10. A high efficiency power supply circuit for a vehicle, comprising:
an alternating current generator (“ACG”);
a rectifier/regulator configured to convert one or more phase AC voltage from the ACG into a direct current (“DC”) output voltage;
a converter configured to decouple the DC output voltage from an output voltage of the converter;
a battery coupled to the output voltage of the converter; and
a controller;
wherein the converter comprises:
a switch having an input coupled to the DC output voltage, an output, and a control input coupled to the controller;
an inductor coupled between the output of the switch and the output of the converter;
a diode coupled between the output of the switch and the output of the converter; and
a capacitor coupled between the output of the converter and ground; and
wherein the controller is configured to provide control signals to the control input of the switch to control a ratio of an ON state of the switch and an OFF state of the switch, thereby regulating the DC output voltage of the rectifier/regulator to the output voltage of the converter.

11. The high efficiency power supply circuit of claim 10, wherein the diode includes a cathode coupled to the output of the switch and an anode coupled to the output of the converter and the inductor includes a first node coupled to the output of the switch and a second node coupled to ground.

12. The high efficiency power supply circuit of claim 10, further comprising a fuse connected between a positive terminal of the battery and the output of the converter.

13. The high efficiency power supply circuit of claim 10, wherein the converter is a buck converter wherein the inductor includes a first node coupled to the output of the switch and a second node coupled to the output of the converter and the diode includes a cathode coupled to the output of the switch and an anode coupled to ground.

14. The high efficiency power supply circuit of claim 10, wherein the switch is a power MOSFET.

15. The high efficiency power supply circuit of claim 10, wherein the controller is configured to adjust one of a pulse width or a duty cycle of the control signals to adjust the output voltage of the converter.

16. The high efficiency power supply circuit of claim 10, wherein the ACG operates at a higher variable voltage level than the output voltage of the converter.

17. The high efficiency power supply circuit of claim 10, wherein the controller is configured to delay operation of the converter after an engine of the vehicle is started for either a predetermined period of time or until the engine reaches a predetermined speed.

18. The high efficiency power supply circuit of claim 10, wherein the controller is configured to control operation of the converter to control a ramp rate of power supplied by the circuit, which in turn controls a ramp rate of torque on an engine of the vehicle.

19. The high efficiency power supply circuit of claim 10, wherein the controller is configured to control the converter to provide a first output voltage for a battery of a first type and a second output voltage for a battery of a second type.

20. A method of supplying power to a vehicle, comprising:
converting, by an alternating current generator (“ACG”) mechanical energy from an engine of the vehicle into one or more phase alternating current (“AC”) voltage;
converting, by a rectifier/regulator coupled to the ACG, the one or more phase AC voltage into a direct current (“DC”) output voltage;
decoupling, by a converter coupled to the rectifier/regulator, the DC output voltage from a load voltage provided by the converter to a battery coupled to an output of the converter;
wherein the converter comprises:
a switch having an input coupled to the DC output voltage, an output, and a control input;
an inductor coupled between the output of the switch and the output of the converter;
a diode coupled between the output of the switch and the output of the converter; and
a capacitor coupled between the output of the converter and ground; and
providing, by a controller, control signals to the control input of the switch to control a ratio of an ON state of the switch and an OFF state of the switch, thereby regulating the DC output voltage of the rectifier/regulator to the load voltage.
